(19) United States
(12) Patent Application Publication
(10) Pub. No.: US 2006/0017482 A1
(43) Pub. Date: Jan. 26, 2006

(54) Compensated schmitt trigger circuit for providing monotonic hysterisis response

(75) Inventors: Virender Singh Chauhan, Delhi (IN); Paras Garg, Ghaziabad (IN)

Correspondence Address: STMicroelectronics Inc.;c/o WOLF, GREENFIELD & SACKS, PC, Federal Reserve Plaza, 600 Atlantic Avenue, BOSTON, MA, 02210-2206, US

(73) Assignee: STMicroelectronics Pvt. Ltd., Uttar Pradesh (IN)

(21) Appl. No.: 11/148,947

(22) Filed: Jun. 9, 2005

(30) Foreign Application Priority Data
Jun. 9, 2004 (IN) 1082/DEL/2004

(51) Int. Cl. H03K 3/037

(52) U.S. Cl. 327/205

(57) ABSTRACT

A compensated Schmitt Trigger circuit for providing a monotonic hysterisis response, the circuit including a plurality of transistors connected in series and coupled to a common input signal at their control inputs, a feedback circuit connected to the output of the plurality of transistors, an inverter coupled to the output of the plurality of transistors and to the feedback circuit for providing a hysterisis response at higher supply voltage, wherein the feedback circuit includes at least one feedback element coupled between the output of said plurality of transistors and input of the inverter for providing a monotonic hysterisis response at the output node of the Schmitt Trigger circuit. The feedback elements are connected/disconnected by control signals that reflect the variations in PVT conditions, and the control signals are derived from the standard Input/Output circuits library for compensation.

### FIELD OF THE INVENTION

The invention relates to Schmitt Trigger circuits that require compensation against Process, Temperature and Voltage (P, V, T) variations for improving hysteresis response at the output. In particular it relates to Schmitt Trigger circuits where compensation is provided to feedback circuit in a standard Schmitt Trigger circuit for providing monotonic hysterisis response as regard to very slow transition and long distance transmission.

### BACKGROUND OF THE INVENTION

A Schmitt Trigger circuit is frequently used to prevent noise from causing false triggering by providing a hysterisis response at the output. When a signal is transmitted along distance through copper traces or a transmission line, noise is introduced in the signal. The receiver at the receiving end does not see a perfect square wave. The signal gets worst when ground bounce and supply bounce (because of pin package inductance) makes logic high and low level a damped sinusoidal.

A Schmitt trigger is an electronic circuit used to turn a signal having slow or asymmetrical transition into a signal with a sharp transition region. This circuit cleans up the input signal from noise and provides very sharp transition. However, a Schmitt circuit characteristic is very much dependent on process and temperature variations because process and temperature directly affect the threshold voltages, which is not under control. Once a chip is fabricated, the process is fixed but operating temperature and voltage change the low and high-level transition threshold points and hence the hysteresis characteristic of the circuit is also affected.

FIG. 1 is a schematic of a conventional Schmitt Trigger circuit. Four stacked parallel input Mosfets M1, M2, M3, M4 and their respective gate electrodes are coupled to the trigger input IN. Depending on the transition of IN, VP or VN, signals are generated which are controlled by the transistor size ratio MP1/M1 and MN1/M4. M5 and M6 makes an inverter to provide a sharp transition at OUT. MP1 and MN1 form a feedback structure to control the switching of the transistors in the circuit. If IN is low then MP1 is off and MN1 is on, OUT is low. As IN increases, M4 begins to turn on and VN starts to decrease. The trip point is defined when IN=Vtn2+VN that is when M3 turns on. When M3 turns on, drain of M3 starts decreasing and turns NMOS MN1 off. Once M3 is on, the transition is very fast. If the transistor size of M3 is large compared to M4 and MN1 then trip point (V_{IH}) is accurately decided by the ratio of MN1/M4. Similarly V_{IL} is decided by the ratio of MP1/M1. Transition points for the circuit can be defined as [1]:

$$\frac{k4}{kN1} = {( \frac{VDDS - {V}_{IH}}{{V}_{IH} - {V}_{TN}} )}^{2}$$

$$\frac{k1}{kP1} = {( \frac{{V}_{IL}}{VDDS - {V}_{IL} - \vert {V}_{TP} \vert} )}^{2}$$

Where: kᵢ=0.5(μCₒₓ)(W/L)ᵢ and V_{TN} is the threshold voltage of n-channel transistors, V_{TP} is the threshold voltage of p-channel transistors (for the above equations, it has been assumed that VT of all NMOS transistors is V_{TN} and PMOS transistors is V_{TP}). As appears from the equations trip points, V_{IH} and V_{IL} are dependent on kᵢ and V_{T} of the transistors. Thus, the circuit is sensitive to the VDDS (positive supply voltage) (as V_{T} of MP1 and MN1 keeps on changing as node VP or VN goes up or comes down respectively with IN), temperature and process. At low supply voltage this circuit does not provide acceptable hysteresis values. With designs involving a wide voltage range, the circuit does not provide a monotonic hysteresis characteristic.

FIG. 2 is a relatively compact design for another conventional Schmitt trigger circuit. A basic inverter latch circuit is employed to achieve hysteresis. This circuit provides an improvement over the prior one, but switching points of this circuit are more difficult to predict. When IN is low, OUT is low and V1 is high, turning MP1 on and MN1 off. As IN rises, transistor M2 has to overcome not only M1 but also MP1, which is controlled by switching of the M3 and M4 pair. Similarly when IN falls from the peak value, then M1 has to overcome M2 and MN1. Thus the input inverter M1/M2 has to fight feedback inverter MP1/MN1 and output inverter M3/M4. Since this circuit is very much dependent on the ratios of three inverters, it is very sensitive to the process, temperature and voltage variations. Again with a wide VDDS range, hysteresis is not monotonic. At low voltage, the circuit exhibits the worst performance.

FIG. 3 is a schematic diagram of a prior art Schmitt trigger circuit, which is an improvement over the conventional Schmitt trigger circuits. This circuit has better speed than the conventional circuit in FIG. 1 and better hysteresis control than the conventional circuit in FIG. 2, therefore its performance is between the two conventional circuits. In this circuit the size of MP1 and MN1 is kept larger (approx double) than the size of M3 and M4 while the sizes of M1, M2, M3 & M4 are kept the same. When IN is low, V1 is high and OUT is low. As IN rises, M1, M3 & M2 determine the trip point. When IN falls, M1, M2 & M4 determine the trip point. This circuit reduces the dependency of the trip point on MP1/MN1 and hence achieves a bit better performance over a conventional latch based structure. However, this circuit is still dependent on the input and output inverter's trip point. Process insensitivity can be reduced a bit by making the channel lengths of M5 and M6 larger, but at the cost of speed degradation.

For very slow transition and long distance transmission a Schmitt trigger circuit with a large value of hysteresis is required. Most of the prior art provides large value hysteresis at high voltage of operation, but are not efficient at low voltage (1.8V or 2.5V) because of threshold variations. A need is therefore exists to have a Schmitt trigger circuit that provides substantially monotonic hysteresis that is relatively less dependent on PVT variations.

In any design standard, the minimum value of VIL and maximum value of VIH for a Schmitt trigger circuit are fixed to take care of noise margins. To satisfy the above requirements for VIL and VIH, the standard Schmitt trigger circuit is designed for the worst possible cases for PVT variations.

FIG. 4 illustrates the transfer curves for the standard circuit of FIG. 1, showing the spread of VIL due to PVT variations. VIL (FS) represents the value of high-to-low transition threshold VIL for a process with fast NMOS and slow PMOS, minimum operating voltage and minimum operating temperature. This is the worst possible value of VIL for a particular design. One can see from the graph that PVT variations cause the V_{IL} to shift in the direction of higher voltage level VDDS thus creating an uncertainty range VIL (SF)-VIL(FS), where VIL(SF) represents the maximum value of VIL for slow NMOS and fast PMOS and maximum operating voltage and temperature. For a whole range of PVT variations, the value of VIL will be contained in the range VIL (SF)-VIL (FS). Similarly as seen from the FIG. 5, the maximum possible value of low-to-high transition threshold VIH is VIH (SF) that represents the value of VIH for slow NMOS and fast PMOS and maximum operating voltage and temperature. The uncertainty range for VIH is VIL (SF)-VIL (FS). Again, for whole range of PVT variations, the value of VIH will be contained in this uncertainty range.

Due to these VIL and VIH spreads with PVT variations, the hysteresis characteristic is not constant over the whole PVT range and the hysteresis values for typical (nominal) process are very low. The situation gets more aggravated at low supply voltages (such as 2.5V, 1.8V).

### THE OBJECT AND SUMMARY OF THE INVENTION

A basic idea of the invention is to reduce the spread of VIL and VIH with PVT variations, so as to provide a substantially monotonic hysteresis characteristic.

The object of the present invention is to obviate the shortcomings of the prior art and provide a compensated Schmitt Trigger circuit for providing monotonic hysterisis response.

Another object of the present invention is to provide a Schmitt Trigger circuit to output a hysteresis characteristic, which is relatively less influenced by process, voltage and temperature variations.

Yet another object of the present invention is to provide a feedback circuit for the Schmitt Trigger circuit to compensate for variations in low and high transition threshold levels to minimize noise in case of signals subjected to variable voltage range.

Another object of the present invention is to provide signals for controlling the size of the feedback transistors for implementing compensation and improving the hysterisis response.

Another object of the present invention is to provide flexibility to trade-off between silicon area and hysteresis values.

To achieve these and other objects, the present invention provides a compensated Schmitt Trigger circuit for providing a monotonic hysterisis response, said Schmitt Trigger circuit comprising:
a plurality of transistors connected in series and coupled to a common input signal at their control inputs to provide an output in response to the transitions in said common input signal,
a feedback circuit connected to the output of said plurality of transistors for controlling the output signals obtained from said plurality of transistors,
an inverter coupled to the output of said plurality of transistors and to said feedback circuit for providing hysterisis response at higher supply voltage, wherein,
said feedback circuit includes at least one feedback element coupled between the output of said plurality of transistors and input of the inverter for providing a monotonic hysterisis response at the output node of the Schmitt Trigger circuit.

The said feedback elements comprising at least two transmission gates connected to the control nodes of at least two transistors at each end of said transmission gates.

The control signals are derived from a compensation cell of a standard Input/Output circuits library for compensation, and said control signals are connected at the control node of said transmission gates to connect/disconnect said feedback elements.

The transistors in said feedback element are PMOS or NMOS transistors.

### BRIEF DESCRIPTION OF THE ACCOMPANYING DRAWINGS

The invention will now be described with reference to the accompanying drawings.

FIG. 1 illustrates the circuit diagram of a conventional Schmitt trigger circuit.

FIG. 2 illustrates the circuit diagram of a relatively compact (as regard to area), conventional Schmitt Trigger circuit.

FIG. 3 illustrates the circuit diagram of another prior art Schmitt Trigger circuit that is an improvement over the above stated prior art circuits.

FIG. 4 illustrates the transfer curves for the prior art Schmitt Trigger circuit as in FIG. 1, showing the spread of High to Low Input transitions threshold due to PVT variations.

FIG. 5 illustrates the transfer curves for the prior art Schmitt Trigger circuit as in FIG. 1, showing the spread of Low to High input transition threshold due to PVT variations.

FIG. 6 illustrates the generic circuit diagram for a compensated Schmitt Trigger for providing monotonic hysterisis response in accordance with the present invention

FIG. 7 illustrates the circuit diagram for a 2-bit Compensated Schmitt Trigger as an embodiment of the present invention

FIG. 8 illustrates the circuit diagram of transmission gate TXP.

FIG. 9 illustrates the circuit diagram of transmission gate TXN.

FIG. 10 illustrates the transfer curves of the instant invention for a given transition threshold range.

FIG. 11 illustrates the transfer curves of the instant invention for a second transition threshold range.

FIG. 12 illustrates the 7-bit code (A6P-A0P) variation with changes in PVT conditions for PMOS transistors.

FIG. 13 illustrates the 7-bit code (A6N-A0N) variation with changes in PVT conditions for NMOS transistors.

FIG. 14 illustrates the comparative variation of hysteresis with PVT for the 2 bit compensated Schmitt Trigger and the standard prior art circuit.

FIG. 15 illustrates the comparative variation of the low level input voltage with PVT for the 2 bit compensated Schmitt Trigger and the standard prior art circuit.

FIG. 16 illustrates the comparative variation of the high level input voltage with PVT for the 2 bit compensated Schmitt Trigger and the standard prior art circuit.

### DETAILED DESCRIPTION

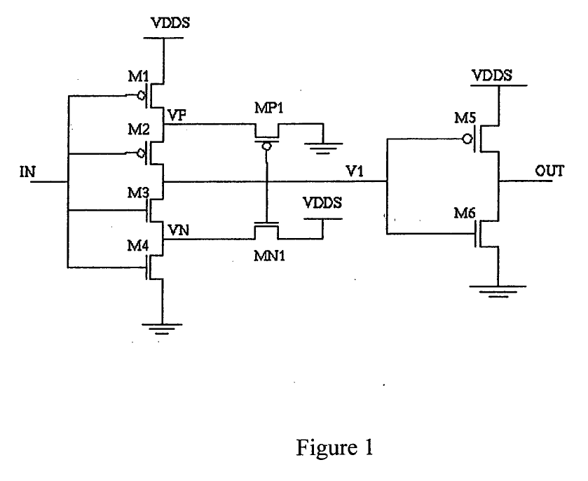

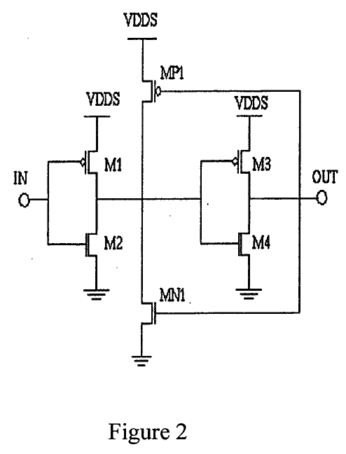

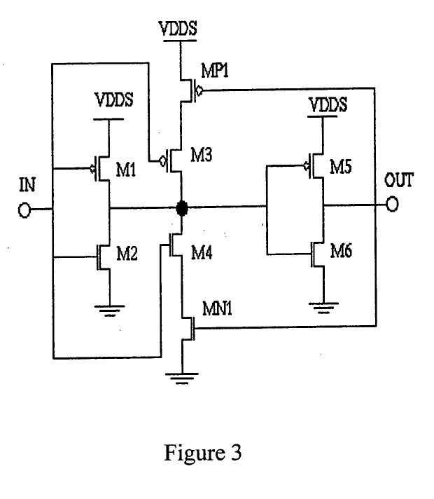

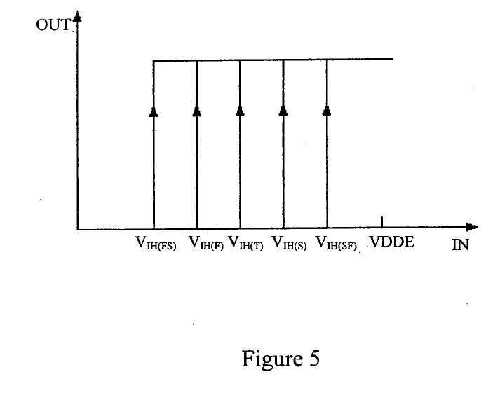

FIGS. 1-5 that illustrate prior art Schmitt Trigger circuit and the transfer curve analysis for the same have been described under the heading Background of the Invention.

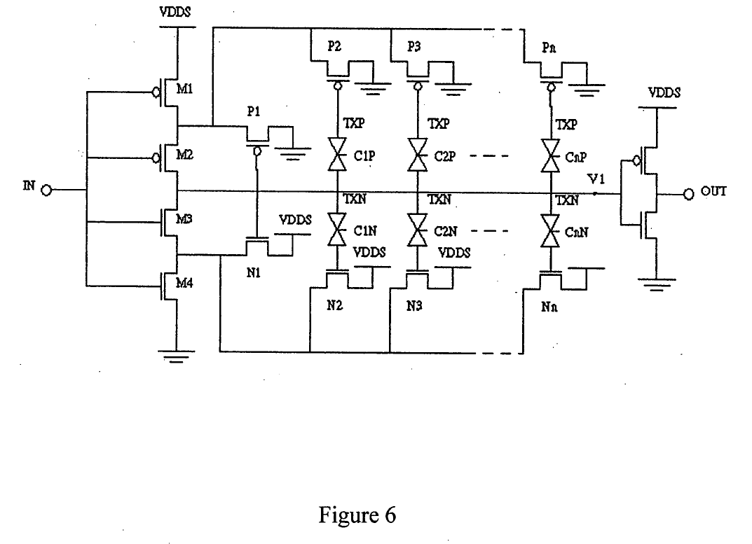

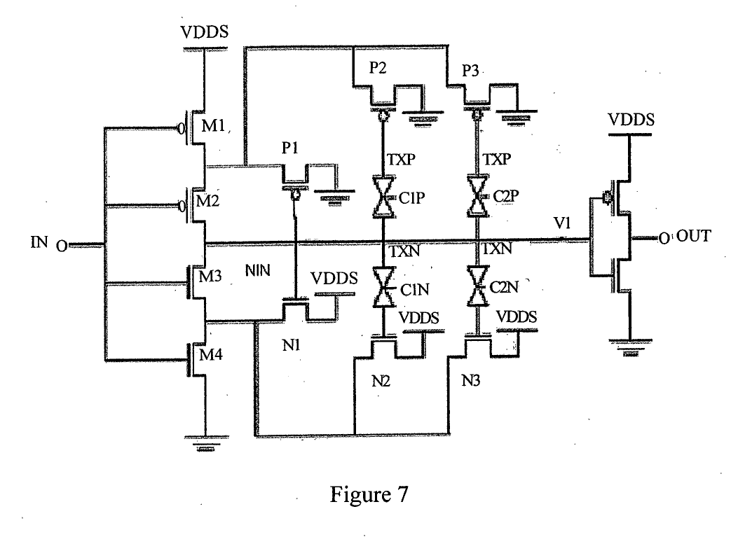

FIG. 6 shows the generic electrical schematic diagrams for a Schmitt trigger circuit in accordance with the present invention and FIG. 7 is a specific electrical schematic diagram, called a 2-bit compensated Schmitt trigger circuit, for a preferred embodiment of a Schmitt trigger circuit in accordance with the present invention. A CMOS Schmitt trigger circuit design in accordance with the present invention provides a reasonably high-speed device having a monotonic hysteresis characteristic over the whole PVT range and provides substantially large values of hysteresis over the whole PVT range for low values of supply also.

In one embodiment, compensated Schmitt trigger circuit includes the standard Schmitt architecture along with feedback circuitry that provides the compensation. The conventional feedback circuitry in a standard circuit, which is responsible for providing hysteresis to the circuit, comprises two transistors and at least one feedback element. In the feedback circuitry, the two transistors are always connected in the circuit, while the transistors of the feedback element are connected through transmission gates. The signals, which control the transmission gates, are continuously updated with the changes in PVT conditions. The control signals for transmission gates are derived from a standard compensation circuit. The compensation circuit used here provides 14 digital output bits that reflect the variations in the PVT conditions. The control signals for the circuit are derived from these 14 bits. These compensation bits are continuously updated with change in PVT conditions. Thus, by controlling the size of feedback transistors in the Schmitt trigger circuit, the spread of VIL towards the higher voltage level and V_{IH} towards the ground level is reduced and hence, the circuit provides a substantially monotonic hysteresis characteristic with high values of hysteresis over the whole PVT range. The present invention will be more fully understood in view of the following detailed description.

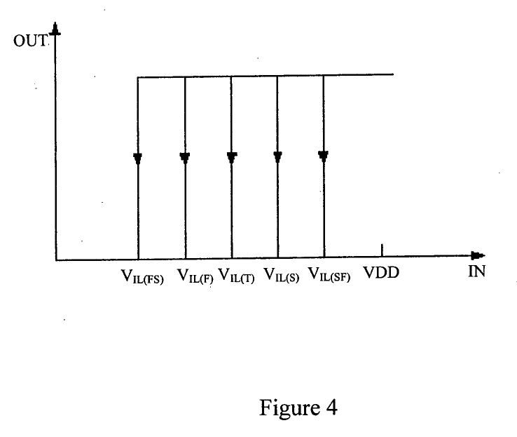

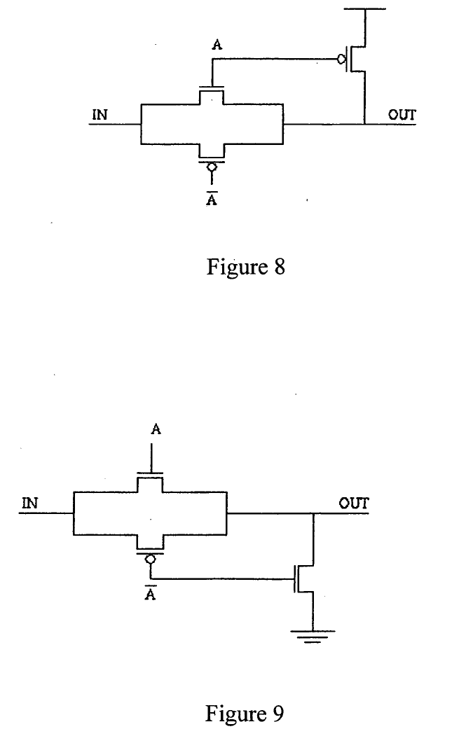

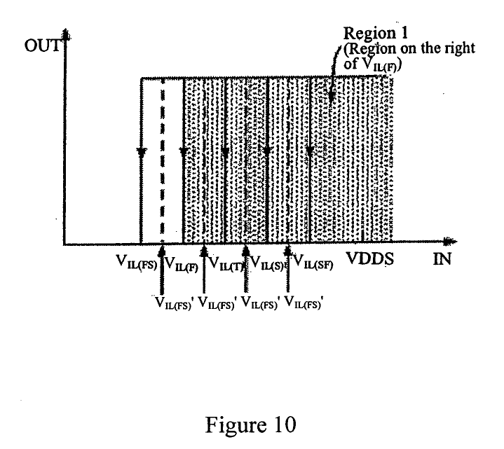

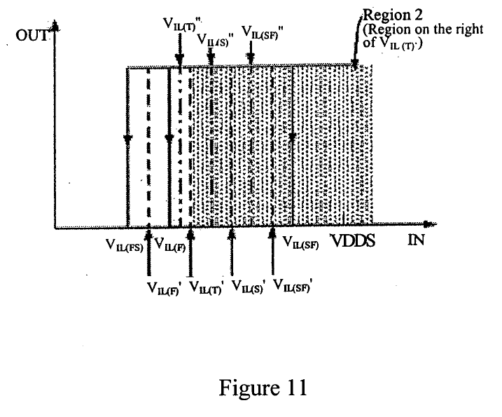

FIG. 7 illustrates the Schmitt Trigger circuit with the additional feedback path to provide compensation against PVT variations. In addition to feedback transistors P1 and N1, two feedback elements are added in the feedback circuitry. The gate of P1 is connected directly to node NIN so that P1 is always included in the circuit. While the gates of the transistors P2 and P3 are connected to node NIN thru transmission gates TXP. The gate of P2 is connected to node NIN if control signal C1P is high and it is connected in parallel with P1, as a result VIL is shifted towards ground level. If C1P is low then the gate of P2 is pulled up to VDDS (see FIG. 8 for TXP circuit), thus causing P2 to operate in cutoff mode. Similarly, if control signal C2P is high, the gate of P3 is connected to node NIN, and it is connected in parallel with P1 and P2 causing V_{IL} to shift further towards ground level. If C2P is low, then P3 is operated in cutoff mode. This configuration can be used to reduce the spread of V_{IL}towards VDDS level if C1P and C2P are enabled/disabled according to PVT variations. For example, suppose that the PVT conditions are such that transition point VIL in the standard circuit corresponds to that of VIL (F) referring to FIG. 4, VIL (F) corresponds to VIL at fast corner and typical voltage and typical temperature). Now, if in the 2-bit compensated Schmitt trigger circuit (FIG. 7), C1P is high for the same PVT conditions, and then P2 comes in parallel with P1. Thus the equivalent size of the feedback PMOS transistor causing the transition point V_{IL (F)} to shift towards ground level to VIL (F)′ (see FIG. 10). The minimum value to which V_{IL (F)} can be shifted is VIL (FS) and relative shift up to VIL (F)′ is determined by the size of transistor P2. If, somehow, it is ensured that C1P remains high under all PVT conditions corresponding to the region on the right of point VIL (F) called regional, then all transition points from VIL (F) to VIL (SF) shift towards a lower voltage level. Let all the transition points, namely VIL (T), VIL (S) and VIL (SF) shift towards the ground level to points VIL (T)′, VIL (S)′ and VIL (SF)′ respectively as shown in FIG. 10. Thus if C1P is enabled in the region 1, then it is possible to reduce the uncertainty range from VIL (SF)-VIL(FS) to VIL(SF)′-VIL(FS) where VIL(SF)′<VIL(SF). Therefore, with C1P enabled (High) in region 1, the new transition points corresponding to VIL (FS), VIL (F), VIL (T), VIL (S) and VIL (SF) are VIL (FS), VIL (F)′, VIL (T)′, VIL (S)′ and VIL (SF)′ respectively and the VIH values remain intact at their previous values. The transition thresholds in the region left to the regional remains intact at their previous values. Now, let us assume that C2P becomes high at VIL (T)′ and remains high under all PVT conditions corresponding to the region on the right of point VIL (T)′ called region 2 as shown in FIG. 11. In region 2 PMOS transistor P3 comes in parallel with P1 and P2. Thus the equivalent size of the feedback PMOS transistor is the effective size of the three PMOS transistors causing the transition point VIL (T)′ to shift further towards ground level to VIL (T)″ as shown in FIG. 11. Due to this configuration, the transition threshold range VIL (T)′-to-VIL (SF)′ is shifted to threshold range VIL (T)″-to-VIL (SF)″. The new thresholds corresponding to VIL (T)′, VIL (S)′ and VIL (SF)′ are VIL (T)″, VIL (S)″ and VIL (SF)″ respectively. The transition thresholds in the region left to the region 2 remains intact at their previous values. Thus, the uncertainty range further reduces from VIL (SF)′-VIL (FS) to VIL (SF)″-VIL(FS) where VIL(SF)″<VIL(SF)′<VIL(SF). The value of VIL (SF)″ depends on the size of PMOS transistors P2 and P3.

Similarly, the NMOS feedback circuitry is implemented with 3 NMOS transistors. The gate of N1 is connected directly to node NIN so that N1 is always included in the circuit. While the gates of the transistors N2 and N3 are connected to node NIN thru transmission gates TXN. The gate of N2 is connected to node NIN if control signal C1N is high and it is connected in parallel with N1. Now, due to the equivalent size of the NMOS feedback transistor VIH is shifted towards higher voltage level. If C1N is low then the gate of N2 is pulled down to ground, thus causing N2 to operate in cutoff mode (see FIG. 9 for TXN circuit). Similarly, if control signal C2N is high, the gate of N3 is connected to node NIN, and it is connected in parallel with N1 and N2 (assuming that C1N is still high) causing VIH to shift further towards VDDS level. If C2N is low, then N3 is operated in cutoff mode. This configuration can be used to reduce the spread of VIH towards ground level if C1N and C2N are enabled/disabled according to PVT variations. Again, for the 2-bit compensated Schmitt trigger circuit (FIG. 7), if C1N is high in the regional, then N2 comes in parallel with N1 and the transition threshold range VIH (SF)-VIH (FS) reduces to transition threshold range VIH (SF)-VIH (FS)′ where VIH (FS)′<VIH (FS). Similarly, in region 2 NMOS transistor N2 comes in parallel with N1 and N2 so that equivalent size of NMOS feedback transistor is (N1+N2+N3). The transition threshold range VIH (SF)-VIH (FS)′ further reduces to transition threshold range VIH (SF)-VIH (FS)″ where VIH (FS)″<VIH (FS)′<VIH (FS) without affecting the VIL values.

The control signals C1P, C2P, C1N and C2N are derived from a standard compensation circuit. A compensation circuit is used to provide digital information depending on operating PVT conditions. The control signals are derived from the same compensation circuit used in almost every standard I/O library for active slew rate control and impedance control in output buffers. The basic principle of operation of this cell is based upon comparing a measurement current with a reference current. The measurement current varies in accordance with PVT conditions whereas the reference current is provided by a band gap reference generator and is highly stable against PVT variations. A simple A/D converter converts the comparison data into a digital compensation code. The compensation circuit used here provides 14 output bits. Out of 14 bits, 7-bit code (A6P-A0P) is used to indicate PVT conditions for PMOS transistors, while the other 7-bit code (A6N-A0N) is used to indicate PVT conditions for NMOS transistors. The code is continuously updated with the variations in PVT conditions.

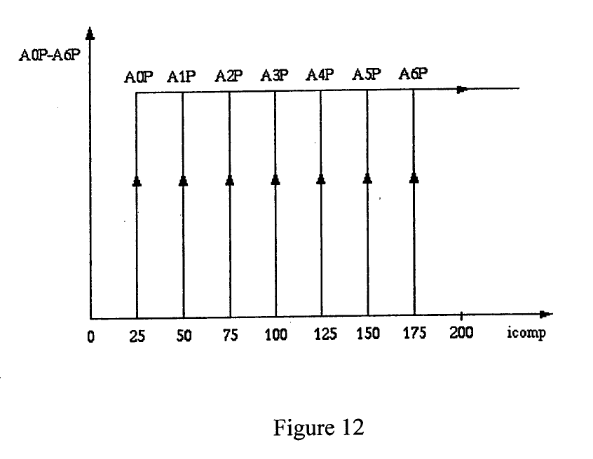

FIG. 12 shows the 7-bit code (A6P-A0P) variation with changes in PVT conditions for PMOS transistors. On the x-axis, a parameter icomp is varied which allows simultaneous control over the PVT conditions. The icomp scale is divided into 200 parts, where icomp=0 represents slow process, maximum temperature and minimum voltage, icomp=100 represents typical (nominal) process, typical temperature and typical voltage, where icomp=200 represents fast process, minimum temperature and maximum voltage.

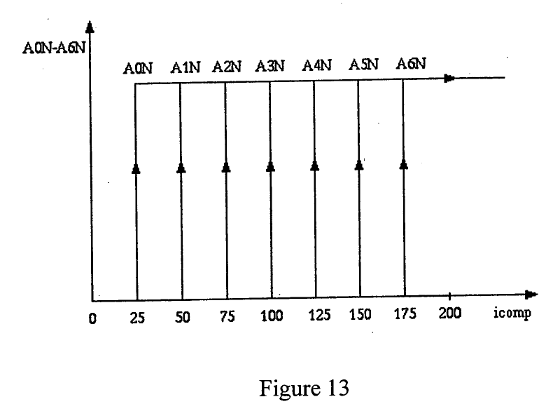

FIG. 13 shows the 7-bit code (A6N-A0N) variation with changes in PVT conditions for NMOS transistors. To derive control signals, we will divide the icomp scale into three regions:

Slow region: characterized by signals A0P/A0N and A1P/A1N (Low on these signals represents slow region).

Fast region: characterized by signals A5P/A5N and A6P/A6N (High on these signals represents fast region).

Typical region: characterized by signals A2P/A2N, A3P/A3N and A4P/A4N (High on these signals represents typical region).

For the 2-bit compensated Schmitt trigger of FIG. 7, the control signals chosen are:
C1P=\overline{(A2P)}+(A5N)
C2P=(A1P)+(A5N), where ‘+’ represents logical OR operation.

Since, C1P is needed to be enabled in the range VIL (F) to VIL (SF), one can find C1P as:

C1P=NOT [(A{overscore (5N))}. (A2P)], where ‘.’ represents logical AND operation. The term ‘(A5N). \overline{(A2P)}’ covers the process corner fast NMOS and slow PMOS. This term is inverted to cover all the corners except FS, which is the requirement of the circuit. Simplifying the expression for C1P, we get;
\overline{C1P}=A5N+A2P

It may be possible that C1P may not get enabled at all the points in the range VIL (F) to VIL (SF). Similarly C2P is derived as:
C2P=(A1P)+\overline{(A5N)}

With the same reasoning, the control signals for VIH control are derived as:
C1N=A1N+\overline{A2P}
C2N=A1N+\overline{A4P}

Simulation results have been depicted below and compared against the standard architecture.

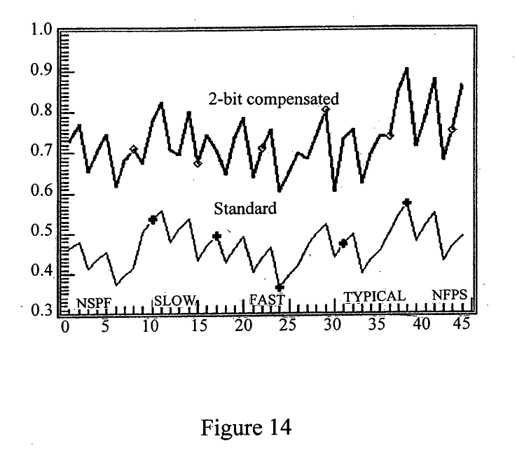

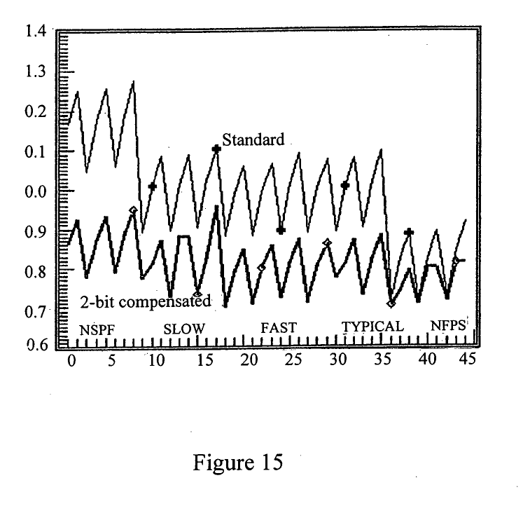

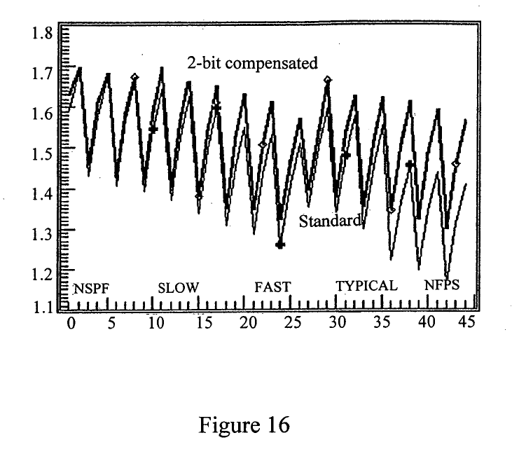

For all the illustrated graphs in FIGS. 14-16, x-axis is the PVT, wherein process, voltage and temp are varying together. There are combinations of PVT (all possible combinations of 3-voltages, 3-temp and 5-process) for which graphs have been plotted. SLOW indicates the process when PMOSs and NMOSs both are slow. NFPS indicates the process when NMOSs is Fast and PMOSs is Slow. NSPF indicates the process when NMOSs is Slow and PMOSs is fast. TYP indicates the nominal process. FAST indicates the process when NMOSs and PMOSs both are fast.

All the graphs are plotted for the 2-bit compensated Schmitt trigger circuit and standard circuit only. The plots clearly show the remarkable improvement over a standard structure across the whole PVT range. The graphs are plotted for both 2.5V and 1.8V supply and they illustrate the spread of VIL, VIH and hysteresis under different conditions of Process, Voltage and Temperature.

It is observed from the simulation results that by providing an additional feedback circuit in the Schmitt Trigger circuit, compensation can be provided against various conditions of Process, Operating Voltage and Temperature for achieving a monotonic hysterisis characteristic.

Thus, in a 2-bit compensated Schmitt trigger, it is possible to reduce the spread of VIL towards VDDE level and spread of VIH towards ground level and hence improve the hysteresis characteristic by increasing hysteresis values. Even if the circuit is reduced to a 1-bit compensated one, the hysteresis values are very improved as compared to that of the standard circuit. The values of VIL (SF)″ and VIH (FS)″ can be improved by increasing the number of transistors in the feedback circuitry and hence by increasing the number of compensated bits. A tradeoff can always be made between the number of compensated bits to be used and the available silicon area. Thus, the present invention provides the basic idea to compensate a Schmitt trigger circuit against the PVT variations and hence to provide a substantially monotonic hysteresis characteristic with high values of hysteresis over the whole PVT range.

The compensation can also be applied in the first stage cascoded inverter to improve hysteresis characteristic. Using the same approach, a back-to-back inverter Schmitt trigger circuit can also be compensated against PVT variations.

Having thus described at least one illustrative embodiment of the invention, various alterations, modifications, and improvements will readily occur to those skilled in the art. Such alterations, modifications, and improvements are intended to be within and scope of the invention. Accordingly, the foregoing description is by way of example only and is not intended as limiting. The invention is limited only as defined in the following claims and the equivalents thereto.

We claim:

1. A compensated Schmitt Trigger circuit for providing a monotonic hysterisis response, said Schmitt Trigger circuit comprising:
a plurality of transistors connected in series and coupled to a common input signal at their control inputs to provide an output in response to transitions in said common input signal,
a feedback circuit connected to the output of said plurality of transistors for controlling the output signals obtained from said plurality of transistors,
an inverter coupled to the output of said plurality of transistors and to said feedback circuit for providing hysterisis response at higher supply voltage,
wherein, said feedback circuit includes at least one feedback element coupled between the output of said plurality of transistors and input of the inverter for providing a monotonic hysterisis response at the output node of the Schmitt Trigger circuit.

2. A compensated Schmitt Trigger circuit as claimed in claim 1, wherein said feedback elements comprise at least two transmission gates connected to the control nodes of at least two transistors at each end of said transmission gates.

3. A compensated Schmitt Trigger circuit as claimed in claim 1, wherein control signals are derived from a compensation cell of a standard Input/Output circuits library for compensation, and said control signals are connected at the control node of said transmission gates to connect/disconnect said feedback elements.

4. A compensated Schmitt Trigger circuit as claimed in claim 2, wherein the transistors in said feedback element are PMOS or NMOS transistors.
